(19) United States
(12) Patent Application Publication
(10) Pub. No.: US 2021/0359209 A1
(43) Pub. Date: Nov. 18, 2021

(54) MASK ASSEMBLY, MAIN MASK, AND MATING MASK

(71) Applicant: Kunshan Go-VisionoxOpto-Electronics Co., Ltd., Kunshan (CN)

(72) Inventors: Bing HAN, Kunshan (CN); Xuliang WANG, Kunshan (CN); Xuan ZHANG, Kunshan (CN); Shuaiyan GAN, Kunshan (CN); Feng GAO, Kunshan (CN)

(21) Appl. No.: 16/340,693

(22) PCT Filed: Nov. 1, 2018
(86) PCT No.: PCT/CN2018/113502

§ 371 Date: Apr. 10, 2019

(30) Foreign Application Priority Data
May 14, 2018 (CN) 201810454366.4

(51) Int. Cl. H01L 51/00; C23C 14/04; C23C 14/24; H01L 51/56

(52) U.S. Cl. CPC H01L 51/0011; C23C 14/042; H01L 51/56; H01L 51/001; C23C 14/24

(57) ABSTRACT

Embodiments of the present disclosure provide a main mask, a mating mask, and a mask assembly. The mask assembly includes a main mask having an evaporation area and a mating mask having a mating area. An effective evaporation area of the main mask corresponds to a display area of a display panel. A first mating area of the mating mask is provided with a first mating opening, and an orthographic projection of the first mating opening on the mating mask completely covers an orthographic projection of the effective evaporation opening on the mating mask. A second mating area of the mating mask shields an ineffective evaporation opening in an ineffective evaporation area of the main mask.

### TECHNICAL FIELD

The present disclosure relates to the field of display manufacturing technologies, and more particularly relates to a mask assembly, a main mask, and a mating mask.

### BACKGROUND

At present, an organic light-emitting diode (OLED) uses vacuum evaporation technology to manufacture an organic light-emitting layer. During a manufacturing process of a device, organic materials are deposited on a substrate located above an evaporation source by high-temperature evaporation. In order to evaporate the organic materials to a specific location as designed, a high-precision metal mask is required. A pre-designed effective opening area is left on the mask (i.e., the high-precision metal mask), and the organic materials can be deposited onto a back plate through the effective opening area to form a predetermined pattern.

As an irregular-shaped display screen having a slot gradually occupy the mainstream market, the demand for the corresponding irregular-shaped screen body is increasing. However, in the process of manufacturing the irregular-shaped screen, the mask is easily wrinkled and affects the bonding with the glass substrate, and finally the evaporation yield is low.

### SUMMARY

Accordingly, the present disclosure provides a mask assembly, which solves the problem that the mask is easily wrinkled during a manufacturing of an irregular-shaped display screen, and improves the yield of the evaporation process.

In order to achieve the above object, the present disclosure provides a mask assembly.

A mask assembly includes:

a main mask having an evaporation area, where the evaporation area has a plurality of evaporation openings, the evaporation area includes an effective evaporation area and an ineffective evaporation area, the evaporation opening located in the effective evaporation area is an effective evaporation opening, the evaporation opening located in the ineffective evaporation area is an ineffective evaporation opening; and

a mating mask having a mating area, where the mating area includes a first mating area and a second mating area, the first mating area corresponds to the effective evaporation area, the second mating area corresponds to the ineffective evaporation area.

The effective evaporation area corresponds to a display area of a display panel. The first mating area is provided with a first mating opening. An orthographic projection of the first mating opening on the mating mask completely covers an orthographic projection of the effective evaporation opening on the mating mask. The second mating area shields the ineffective evaporation opening in the ineffective evaporation area.

In the aforementioned mask assembly, the main mask is supported by the mating mask, for example, the mating mask is laminated with the main mask. In addition, the mating mask not only supports an area of the main mask without being slotted, but also can be placed under the effective evaporation area of the main mask with the effective evaporation opening. The width of the mating mask can be increased to provide sufficient support for the main mask to improve the evaporation yield. Moreover, a wider mating mask is provided with the first mating area that cooperates with the effective evaporation area, such that the evaporation material of the main mask will not be affected. Furthermore, the mating mask is further provided with the second mating area, which corresponds to the ineffective evaporation area and shields the ineffective evaporation openings in the ineffective evaporation area. The ineffective evaporation area can correspond to a slotted area of the irregular-shaped screen, and the ineffective evaporation area is provided with the ineffective evaporation openings, the ineffective evaporation openings and the openings in the slotted area outside the effective evaporation area are shielded from each other. The main mask is only provided with the effective evaporation openings corresponding to the display area of the irregular-shaped screen to form an irregular-shaped effective evaporation area, and the ineffective evaporation openings are provided outside the irregular-shaped effective evaporation area, which can average the stress at the edge of the effective evaporation area, and prevent the edge of the effective evaporation area from being wrinkled due to uneven force, thereby improving the evaporation yield. In addition, after the ineffective evaporation opening that averages the stress is provided on the main mask, the ineffective evaporation opening in the ineffective evaporation area is shielded by the second mating area on the mating mask, so that materials are blocked from passing through the ineffective evaporation opening during the evaporation process, thereby finally manufacturing an irregular-shaped display panel having a slotted area.

In one of the embodiments, the main mask includes an evaporation surface and a glass surface, the evaporation surface is disposed facing to an evaporation source, the glass surface is disposed away from the evaporation source. The mating mask is laminated with the evaporation surface of the main mask.

In one of the embodiments, the main mask includes at least two sub-masks. The ineffective evaporation area includes a first ineffective evaporation area located between adjacent two sub-masks of the main mask. A portion of the adjacent two sub-masks adjacent to the first ineffective evaporation area is not provided with an irregular-shaped opening area. A plurality of the ineffective evaporation openings are distributed in the first ineffective evaporation area. The mating mask includes a first mating mask, the first mating area of the first mating mask corresponds to a portion of the effective evaporation area of the adjacent two sub-masks adjacent to the first ineffective evaporation area. The second mating area corresponds to the first ineffective evaporation area and shields the ineffective evaporation openings in the first ineffective evaporation area.

In one of the embodiments, the main mask includes at least one sub-mask, the sub-mask has an irregular-shaped opening area, and the irregular-shaped opening area constitutes at least a part of the ineffective evaporation area.

In one of the embodiments, the ineffective evaporation area includes a second ineffective evaporation area. The second ineffective evaporation area is located at an end of the main mask and corresponds to the irregular-shaped opening area of the sub-mask at the end. The mating mask includes a second mating mask, the first mating area of the second mating mask corresponds to the effective evaporation area of the sub-mask located at the end of the main mask. The second mating area corresponds to the second ineffective evaporation area and shields the ineffective evaporation opening in the second ineffective evaporation area.

In one of the embodiments, the main mask includes at least two sub-masks, the ineffective evaporation area includes a third ineffective evaporation area, the third ineffective evaporation area includes a third main ineffective evaporation area and a third auxiliary ineffective evaporation area. The third main ineffective evaporation area is located between adjacent two sub-masks. The third auxiliary ineffective evaporation area corresponds to the irregular-shaped opening area of the sub-mask. The mating mask includes a third mating mask, the first mating area of the third mating mask corresponds to a portion of the effective evaporation area of the adjacent two sub-masks. The second mating area corresponds to the third main ineffective evaporation area and the third auxiliary ineffective evaporation area, and shields the ineffective evaporation opening in the third main ineffective evaporation area and the third auxiliary ineffective evaporation area.

In one of the embodiments, in the sub-masks located at both sides of the third main ineffective evaporation area, the irregular-shaped opening area of any one of the sub-masks is adjacent to the third main ineffective evaporation area.

In one of the embodiments, the irregular-shaped opening areas of the two sub-masks located at both sides of the third main ineffective evaporation are disposed at both sides of the third main ineffective evaporation area, respectively.

In one of the embodiments, a projection of the irregular-shaped opening area on a main body of the main mask has a shape of circular or polygonal with an arcuate chamfer.

In one of the embodiments, the evaporation area includes a first transverse centerline and a first longitudinal centerline perpendicular to each other. The evaporation area is axisymmetric relative to the first transverse centerline and/or the first longitudinal centerline.

In one of the embodiments, the mating area includes a second transverse centerline and a second longitudinal centerline perpendicular to each other. The mating area is axisymmetric relative to the second transverse centerline and/or the longitudinal centerline.

In one of the embodiments, when the main mask is laminated with the mating mask, the first longitudinal centerline coincides with the second longitudinal centerline.

In one of the embodiments, the second mating area is provided with a plurality of second mating openings. An orthographic projection of the second mating opening on the mating mask is completely offset from an orthographic projection of the ineffective evaporation opening on the mating mask.

In one of the embodiments, the orthographic projection of the first mating opening on the mating mask completely coincides with the orthographic projection of the effective evaporation opening on the mating mask.

The present disclosure further provides a main mask. The main mask has an evaporation area, the evaporation area includes an effective evaporation area and an ineffective evaporation area. The effective evaporation area is provided with a plurality of effective evaporation openings penetrating the main mask. The ineffective evaporation area is provided with a plurality of ineffective evaporation openings penetrating the main mask, and the effective evaporation area corresponds to a display area of a display panel.

The present disclosure further provides a mating mask configured to be laminated with a main mask. The main mask includes an effective evaporation area and an ineffective evaporation area. A plurality of effective evaporation openings are distributed in the effective evaporation area, and a plurality of ineffective evaporation openings are distributed in the ineffective evaporation area. The mating mask has a mating area, the mating area includes a first mating area and a second mating area. The first mating area is provided with a plurality of first mating openings. An orthographic projection of each of the first mating openings on the mating mask completely covers an orthographic projection of each of the effective evaporation openings on the mating mask. The second mating area shields the plurality of ineffective evaporation openings in the ineffective evaporation area.

In one of the embodiments, the mating area includes the first mating area and the second mating area. The second mating area corresponds to a slotted area of a display panel, the first mating area surrounds the second mating area.

In one of the embodiments, the mating area includes the first mating area and the second mating area. There are two first mating areas, the second mating area is located between adjacent two first mating areas.

In one of the embodiments, the mating area includes the first mating area and the second mating area. There are two first mating areas. The second mating area includes a second main mating area and a second auxiliary mating area. The second main mating area is located between adjacent two first mating areas. The second auxiliary mating area corresponds to an irregular-shaped slotted area of a display panel. The second auxiliary mating area is located on either side or opposite sides of the second main mating area.

### BRIEF DESCRIPTION OF THE DRAWINGS

FIG. 1 is a schematic view of a mask assembly according to an embodiment of the present disclosure;

FIG. 2a is a schematic view of a main mask in the mask assembly of FIG. 1;

FIG. 2b is a schematic view of a mating mask in the mask assembly of FIG. 1;

FIG. 3 is a schematic view of a mask assembly according to another embodiment of the present disclosure;

FIG. 4a is a schematic view of a main mask in the mask assembly of FIG. 3;

FIG. 4b is a schematic view of a mating mask in the mask assembly of FIG. 3;

FIG. 5 is a schematic view of a mask assembly according to yet another embodiment of the present disclosure;

FIG. 6 is a schematic view of a mask assembly according to yet another embodiment of the present disclosure;

FIG. 7 is a schematic view of a mask assembly according to yet another embodiment of the present disclosure;

FIG. 8 is a schematic view of a mask assembly according to yet another embodiment of the present disclosure;

FIG. 9 is a schematic view of a first mating mask according to an embodiment of the present disclosure;

FIG. 10 is a schematic view of a second mating mask according to an embodiment of the present disclosure;

FIG. 11 is a schematic view of a third mating mask according to an embodiment of the present disclosure;

FIG. 12 is a schematic view of a third mating mask according to yet another embodiment of the present disclosure;

FIG. 13a is a partial schematic view of an ineffective evaporation area in the mask assembly of FIG. 1;

FIG. 13b is a partial schematic view of a second mating area in the mask assembly of FIG. 1; and

FIG. 14 is a schematic view showing a lamination of an ineffective evaporation area and a second mating area in the mask assembly of FIG. 1.

### DETAILED DESCRIPTION OF THE EMBODIMENTS

In order to facilitate the understanding of the present disclosure, embodiments of the disclosure are described more fully hereinafter with reference to the accompanying drawings. The various embodiments of the disclosure may, however, be embodied in many different forms and should not be construed as limited to the embodiments set forth herein. Rather, these embodiments are provided so that this disclosure will be thorough and complete, and will fully convey the scope of the disclosure to those skilled in the art.

It will be understood that when an element is referred to as being “fixed” to another element, it can be directly on the other element or intervening elements may be present. when an element is referred to as being “connected” or “coupled” to another element, it can be directly connected or coupled to the other element or intervening elements may be present.

Unless otherwise defined, all terms (including technical and scientific terms) used herein have the same meaning as commonly understood by one of ordinary skill in the art to which this disclosure belongs. The terms used herein in the specification of the present disclosure are for the purpose of describing specific embodiments only and are not intended to limit the present disclosure. The terms “and/or” used herein includes any and all combinations of one or more associated listed items.

As described in the background art, when a mask in the related art is used to manufacture an irregular-shaped display screen, there is a problem that the mask is easily wrinkled. The inventors have found that the fundamental reason for this problem is that when the mask is used to manufacture the irregular-shaped screen, the evaporation area provided with the evaporation opening on the mask matches the display area of the irregular-shaped screen. For example, when a shape of the display area is an asymmetrical irregular shape, the evaporation area on the mask also has an asymmetrical irregular shape. In the tensioning process of the mask having the evaporation area with the irregular shape, the edge of the irregular-shaped evaporation area is easily wrinkled due to uneven force, which may affect the bonding of the mask and the glass substrate, and finally affect the evaporation effect and reduce the yield.

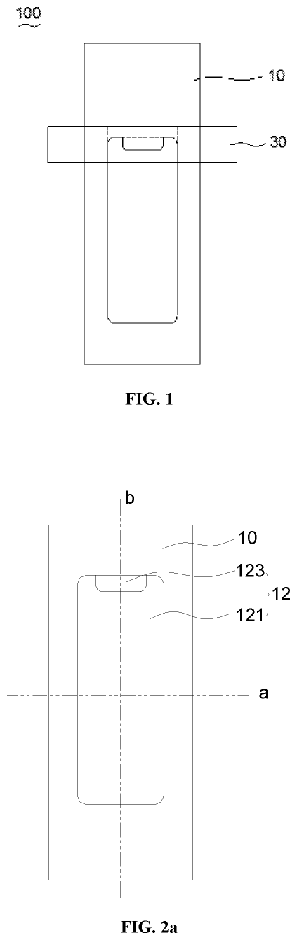

Referring to FIGS. 1 to 4, accordingly, an embodiment of the present disclosure discloses a mask assembly 100, which includes a main mask 10 and a mating mask 30 that are laminated disposed. The mating mask 30 and the main mask 10 are both adapted to be disposed on a support frame. Specifically, the mating mask 30 and the main mask 10 can be tightly welded to the support frame. In addition, the main mask 10 extends along a first direction, the mating mask 30 extends along a second direction and is placed under the main mask 10. The support frame supports the main mask 10 through the mating mask 30. The first direction is preferably substantially perpendicular to the second direction.

Preferably, the main mask 10 includes an evaporation surface and a glass surface. The evaporation surface is adapted to be disposed facing an evaporation source, and the glass surface is adapted to be disposed away from the evaporation source. In order to further improve the evaporation effect of the mask assembly, the mating mask 30 in the present embodiment is laminated with the evaporation surface of the main mask 10.

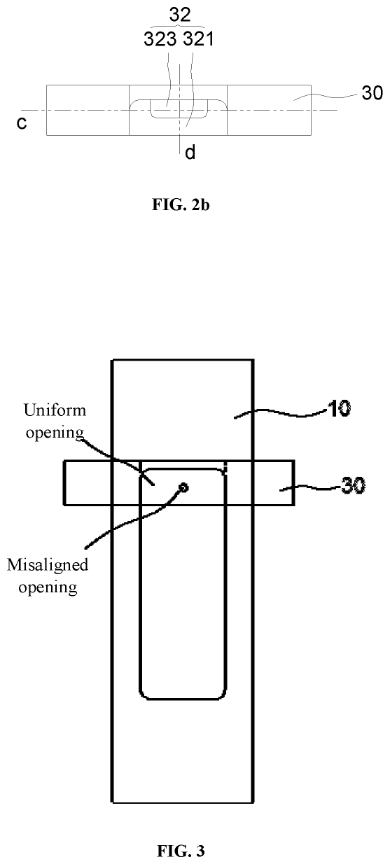

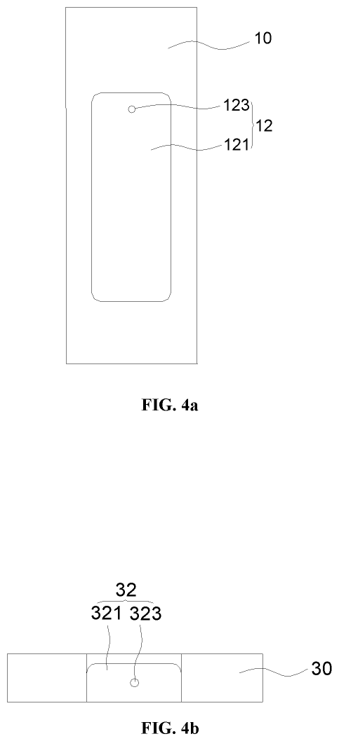

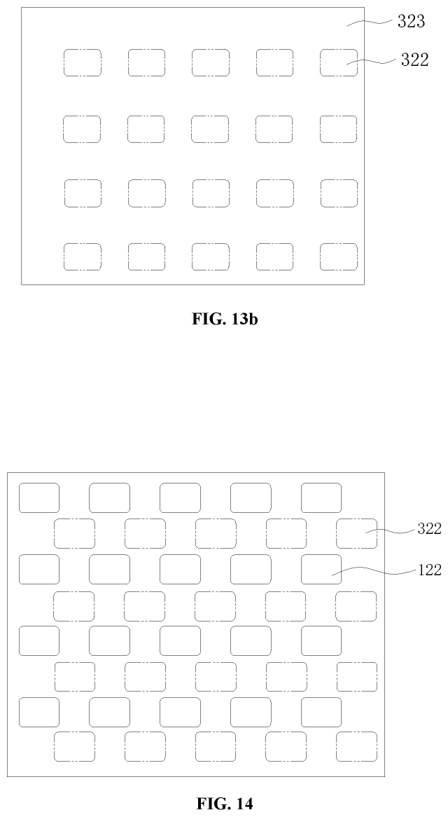

Referring to FIG. 2a and FIG. 4a, the main mask 10 has an evaporation area 12. The evaporation area 12 has a plurality of evaporation openings and includes an effective evaporation area 121 and an ineffective evaporation area 123. The evaporation opening located in the effective evaporation area 121 is an effective evaporation opening (not shown), and the evaporation opening located in the ineffective evaporation area 123 is an ineffective evaporation opening 122 (referring to FIG. 13a).

Referring to FIG. 2b and FIG. 4b, the mating mask 30 has a mating area 32. The mating area 32 includes a first mating area 321 and a second mating area 323. The first mating area 321 corresponds to at least a portion of the effective evaporation area 121 and is provided with a first mating opening (not shown). The effective evaporation area 121 corresponds to the display area of the display panel. An orthographic projection of the first mating opening on the mating mask 30 completely covers an orthographic projection of the effective evaporation opening on the mating mask 30. In other words, the first mating opening corresponds to the effective evaporation opening, and the first mating opening is greater than or equal to the corresponding effective evaporation opening. The second mating area 323 corresponds to the ineffective evaporation area 123 and shields the ineffective evaporation openings 122 in the ineffective mating area 123.

In the aforementioned mask assembly 100, the effective evaporation area 121 corresponds to the display area of the display panel, and materials are deposited on a substrate through the effective evaporation opening in the effective evaporation area 121, thus the display panel having the aforementioned display area is finally obtained.

The mating mask 30 is laminated with the main mask 10, the support frame supports the main mask 10 by the mating mask 30. The first mating area 321 corresponding to at least a portion of the effective evaporation area 121 is disposed on the mating mask 30. The first mating area 321 is provided with a plurality of first mating openings. The orthographic projection of the first mating opening on the mating mask 30 completely covers the orthographic projection of the effective evaporation opening on the mating mask 30. In other words, an opening range of the effective evaporation opening in the at least a portion of the effective evaporation area 121 is within the range of the first mating opening. Thus, the evaporation material can continue to pass through the effective evaporation opening after passing through the first mating opening, and finally be deposited on the substrate.

In this way, the mating mask 30 not only supports an area of the main mask 10 without being slotted, but also can be placed under the effective evaporation area 121 of the main mask 10 with the effective evaporation opening. The width of the mating mask 30 can be increased (the widening direction is consistent with the first direction) to provide sufficient support for the main mask 10 to improve the evaporation yield. In addition, the wider mating mask 30 is provided with the first mating area 321 that cooperates with the effective evaporation area 121, such that the evaporation material of the main mask 10 will not be affected.

Moreover, the mating mask 30 is further provided with the second mating area 323, which corresponds to the ineffective evaporation area 123 and shields the ineffective evaporation openings 122 in the ineffective evaporation area 123. The ineffective evaporation area 123 can correspond to a slotted area of the irregular-shaped screen, and the ineffective evaporation opening 122 is provided in the ineffective evaporation area 123. The main mask 10 is provided with the effective evaporation openings corresponding to the display area of the irregular-shaped screen to form an irregular-shaped effective evaporation area 121, and the ineffective evaporation openings 122 are provided outside the irregular-shaped effective evaporation area 121, which can average the stress at the edge of the effective evaporation area 121, and prevent the edge of the effective evaporation area 121 from being wrinkled due to uneven force, thereby improving the evaporation yield.

In addition, after the ineffective evaporation opening 122 that averages the stress is provided on the main mask 10, the ineffective evaporation openings 122 in the ineffective evaporation area 123 are shielded by the second mating area 323 on the mating mask 30. During the evaporation process, the second mating area 323 can block the materials from passing through the ineffective evaporation opening 122 to finally manufacture the irregular-shaped display panel having the slotted area.

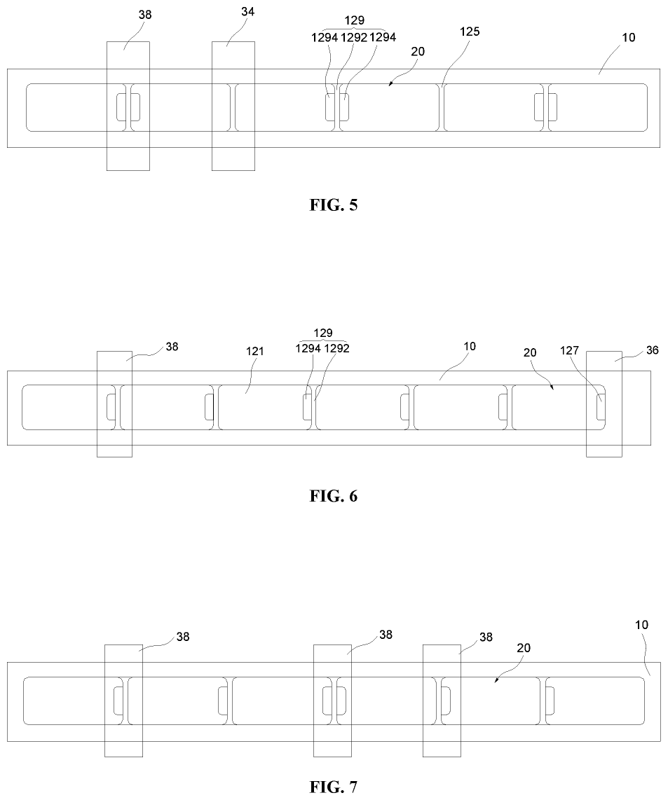

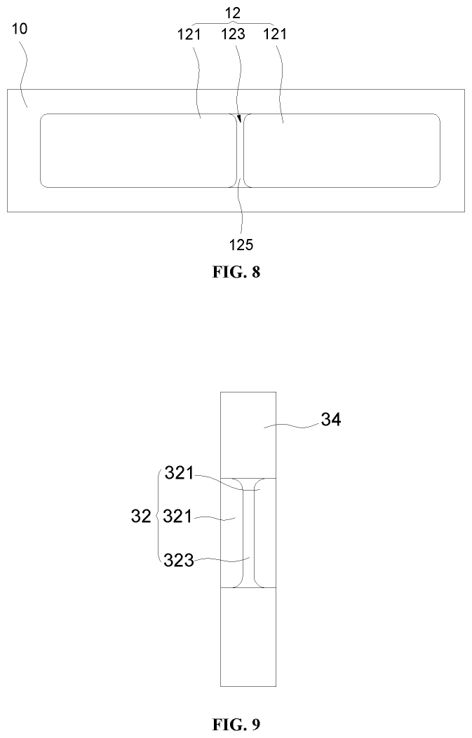

Referring to FIGS. 5, 8 and 9, in one embodiment, the main mask 10 includes at least two sub-masks 20. One sub-mask corresponds to one display panel, such that the evaporation of a plurality of the display panels can be simultaneously preformed. The ineffective evaporation area 123 includes a first ineffective evaporation area 125, which is located between adjacent two sub-masks 20 of the main mask 10. In addition, a portion of the adjacent two sub-masks 20 proximately to the first ineffective evaporation area 125 is not provided with the irregular-shaped opening area, and the plurality of ineffective evaporation openings 122 are distributed in the first ineffective evaporation area 125. The mating mask 30 includes a first mating mask 34. The first mating area 321 of the first mating mask 34 corresponds to the portion of the effective evaporation area 121 on the adjacent two sub-masks 20 proximately to the first ineffective evaporation area 125. The second mating area 323 corresponds to the first ineffective evaporation area 125 and shields the ineffective evaporation opening 122 in the first ineffective evaporation area 125.

The first ineffective evaporation area 125 is shielded by the second mating area 323 of the first mating mask 34 to isolate the adjacent two sub-masks 20, and at least two separate display panels are finally produced. The first ineffective evaporation area 125 is disposed between the adjacent two sub-masks 20, and the ineffective evaporation opening 122 is provided in the first ineffective evaporation area 125, so that the stress on the edge of the effective evaporation area 121 of each of the sub-masks 20 can be better averaged, and the tensioning accuracy is improved.

In addition, the first mating mask 34 is not only disposed corresponding to the width of the first ineffective evaporation area 125, but also is placed corresponding to the effective evaporation area 121 around the first ineffective evaporation area 125, so that the width of the first mating mask 34 becomes greater. Therefore, the first mating mask 34 is prevented from easily affecting the evaporation effect due to the less width and insufficient support when the first mating mask 34 is disposed only corresponding to the narrow first ineffective evaporation area 125. The mask assembly 100 in the present embodiment can be used to manufacture a plurality of display panels with a narrow interval.

In another embodiment, the sub-mask 20 has an irregular-shaped opening area, and the irregular-shaped opening area is provided with a plurality of evaporation openings. The irregular-shaped opening area is also the ineffective evaporation area, and the evaporation opening in the irregular-shaped opening area is the ineffective evaporation opening 122. After the irregular-shaped opening area is disposed on the sub-mask 20, the sub-mask can be used to manufacture the display panel having the irregular-shaped slotted area, and the irregular-shaped opening area of the sub-mask 20 is disposed corresponding to the slotted area of the display panel.

In addition, a projection of the irregular-shaped opening area of the sub-mask 20 on a main body of the main mask 10 has a shape of circular or polygonal with an arcuate chamfer. Referring to FIGS. 1 to 2, the irregular-shaped opening area on the sub-mask 20 corresponds to the ineffective evaporation area 123 and has a shape of rectangular with an arcuate chamfer, so as to correspondingly obtain an irregular-shaped display panel having a rectangular notch. Referring to FIGS. 3 to 4, the irregular-shaped opening area on the sub-mask 20 corresponds to the ineffective evaporation area 123, and the ineffective evaporation area 123 has a shape of circular, so as to correspondingly obtain an irregular-shaped display panel having a circular notch. In alternative embodiments, the shape of the irregular-shaped opening area on the sub-mask 20 may also be other polygons with arcuate chamfers, or other irregular shapes, and only rectangular and circular shapes are taken as an example.

Referring to FIGS. 6 and 10, in one of the embodiments, the ineffective evaporation area 123 includes a second ineffective evaporation area 127, which is located at one end of the main mask 10 and corresponds to the irregular-shaped opening area of the sub-mask 20. The mating mask 30 includes a second mating mask 36. The first mating area 321 of the second mating mask 36 corresponds to at least a portion of the effective evaporation area 121 of the sub-mask 20 located on one end of the main mask 10. The second mating area 323 corresponds to the second ineffective evaporation area 127 and shields the ineffective evaporation opening in the second ineffective evaporation area 127. In this case, the second mating mask 36 is placed at one end of the main mask 10 and is disposed proximately to an end of the irregular-shaped opening area of the sub-mask 20 located at one end of the main mask 10.

The second ineffective evaporation area 127 on the main mask 10 is shielded by the second mating area 323 on the second mating mask 36, and no material is deposited on the substrate corresponding to the slotted area of the display panel to manufacture the irregular-shaped display panel. In addition, the effective evaporation area 121 around the second ineffective evaporation area 127 corresponds to the first mating opening on the second mating mask 36. After the second mating mask 36 is placed under the effective evaporation area 121, the first mating opening provided in an area corresponding to the effective evaporation area 121 allows the evaporation material to pass through, thereby preventing the second mating mask 36 from affecting the evaporation of the effective evaporation area 121.

In this way, during the manufacturing of the irregular-shaped display panel having the slotted area, the ineffective evaporation opening 122 is provided in the second ineffective evaporation area 127 of the main mask 10 to average the stress on the edge of the effective evaporation area 121, thereby reducing wrinkles. In addition, the ineffective evaporation opening 122 is shielded by the second mating area 323 on the mating mask 30, and no material is deposited on the position on the substrate corresponding to the slotted area to finally obtain the irregular-shaped display panel, while ensuring the evaporation yield.

Referring to FIGS. 5 to 7 and FIGS. 11 to 12, in another embodiment, the ineffective evaporation area 123 includes a third ineffective evaporation area 129. The third ineffective evaporation area 129 includes a third main ineffective evaporation area 1292 and a third auxiliary ineffective evaporation area 1294. The third main ineffective evaporation area 1292 is located between adjacent two sub-masks 20, and the third auxiliary ineffective evaporation area 1294 corresponds to the irregular-shaped opening area of the sub-mask 20. The mating mask 30 includes a third mating mask 38. The first mating area 321 of the third mating mask 38 corresponds to the portion of the effective evaporation area 121 of the adjacent two sub-masks 20. The second mating area 323 corresponds to the third main ineffective evaporation area 1292 and the third auxiliary ineffective evaporation area 1294, and shields the ineffective evaporation opening 122 in the third main ineffective evaporation area 1292 and the third auxiliary ineffective evaporation area 1294. In this case, the third mating mask 38 is located in an non-end area of the main mask 10 and is placed between the adjacent two sub-masks 20. The third main ineffective evaporation area 1292 is shielded by the second mating area 323 of the third mating mask 38, and the adjacent two sub-masks 20 are isolated to manufacture a plurality of individual display panels. In addition, the third auxiliary ineffective evaporation area 1294 is also shielded by the second mating area 323 of the third mating mask 38 to manufacture the irregular-shaped display panel having the slotted area.

Moreover, in the sub-masks 20 located at both sides of the third main ineffective evaporation area 1292, the irregular-shaped opening area of any one of the sub-masks 20 is adjacent to the third main ineffective evaporation area 1292, and the third auxiliary ineffective evaporation area 1294 corresponds to the irregular-shaped opening area of the sub-mask 20. In this way, one third auxiliary ineffective evaporation area 1294 is disposed on either side of the third main ineffective evaporation area 1292 to manufacture the irregular-shaped display panel. Alternatively, in the two sub-masks 20 located at both sides of the third main evaporation area 1292, the irregular-shaped opening areas of each of the sub-masks 20 are disposed on both sides of the third main ineffective evaporation area 1292, respectively. The third auxiliary ineffective evaporation area 1294 corresponds to the irregular-shaped opening area of the sub-mask 20. In this way, the third auxiliary ineffective evaporation areas 1294 are disposed on both opposite sides of the third main ineffective evaporation area 1292. This arrangement is advantageous in reducing wrinkles when manufacturing a plurality of irregular-shaped display panels at the same time. In other word, the third main ineffective evaporation area 1292 is shielded by the third mating mask 38 to isolate the adjacent two sub-masks 20, while also shielding the third auxiliary ineffective evaporation area 1294, thereby finally producing the irregular-shaped display panel.

Referring to FIGS. 13a, 13b, and 14, in one of the embodiments, the second mating area 323 is provided with a plurality of second mating openings 322. An orthographic projection of the ineffective evaporation opening 122 on the mating mask 30 is completely offset from an orthographic projection of the second mating opening 322 on the mating mask 30, so that a solid portion of the second mating area 323 in which the second mating opening 322 is not provided can shield the ineffective evaporation opening 122, thereby preventing the evaporation material from passing through the ineffective evaporation opening 122, and thus the evaporation material cannot be evaporated to an area corresponding to the ineffective evaporation area 123, and finally the irregular-shaped screen having a notch is obtained. In addition, with respect to the mating area 32 of the mating mask 30 disposed corresponding to the evaporation area 12 of the main mask 10, the first mating opening and the second mating opening 122 are provided in the first mating area 321 and the second mating area 323 in the mating area 32, respectively, so that the area of the mating mask 30 as a whole provided with the opening is uniform, so as to avoid unevenness of the opening area and wrinkle of the mating mask 30. In this way, during the evaporation process, the wrinkles of the main mask 10 can be avoided, and at the same time, the wrinkles of the mating mask 30 cooperated with the main mask 10 can be avoided, and the evaporation yield can be improved.

In other words, according to the actual production requirements, when the display screen is manufactured, the main mask area and the mating mask area corresponding to the area in which the display screen does not need to be displayed is provided with a completely misaligned opening, so that the evaporation material does not pass through the main mask 10 and the mating mask 30 to an area where evaporation is not required. A portion on the mating mask 30 corresponding to the effective evaporation area 121 is provided with a uniform opening to allow the evaporation material to pass through. The area where evaporation is not required is also the ineffective evaporation area as referred to herein. As described above, the ineffective evaporation area 123 may be the slotted area of the irregular-shaped display screen, or may be an isolation area between adjacent two display screens, or may be a combination of the isolation area and the slotted area. The specific shape of the ineffective evaporation area 123 is not limited hereto.

In the present embodiment, preferably, the orthographic projection of the first mating opening on the mating mask 30 completely coincides with the orthographic projection of the effective evaporation opening on the mating mask 30. In other words, the size and position of the first mating opening are consistent with those of the effective evaporation opening, thus allowing the material to pass through the opening in the first mating area 321 without interference after passing through the opening of the effective evaporation area 121.

It should be understood that, in alternative embodiments, the orthographic projection area of the first mating opening on the mating mask 30 may be larger than the orthographic projection area of the effective evaporation opening on the mating mask 30. The first mating opening in the first mating area 321 is larger, the effective evaporation opening in the effective evaporation area 121 is smaller. The material can be deposited on the substrate after passing through the smaller effective evaporation opening in the effective evaporation area 121 and then through the larger first mating opening, so that the mounting accuracy requirements of the main mask 10 and the mating mask 30 can be reduced.

Referring to FIG. 2a, in one embodiment, the evaporation area 12 includes a first transverse centerline a and a second longitudinal centerline b that are perpendicular to each other. The evaporation area 12 is axisymmetric relative to the first longitudinal centerline b. In this way, when the irregular-shaped display panel having the slotted area is manufactured, the uniformity of the evaporation area 12 on the entire main mask 10 is ensured, the uniformity of the opening area on the main mask 10 can be ensured after the opening is provided in the evaporation area 12, thereby preventing the main mask 10 from wrinkling due to uneven opening area during tensioning.

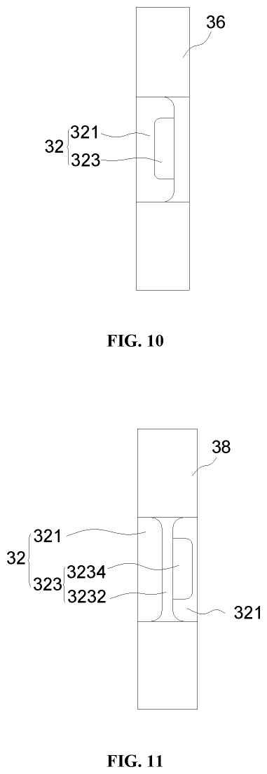

Referring to FIG. 2b, the mating area 32 includes a second transverse centerline c and a second longitudinal centerline d that are perpendicular to each other. The mating area 32 is axisymmetric relative to the second longitudinal centerline d, ensuring the uniformity of the mating area 32 in the direction perpendicular to the extension of the mask 30. Alternatively, referring to FIG. 9, the mating area 32 is axisymmetric relative to the second transverse centerline and the second longitudinal centerline, thereby ensuring the uniformity of the mating area 32 in the transverse and longitudinal directions of the mating mask 30, and avoiding the wrinkling of the mating mask 30 due to uneven opening area during tensioning.

In addition, referring to FIGS. 1 to 2, when the mating mask 30 and the main mask 10 are cooperatively mounted, the main mask 10 is laminated with the mating mask 30, the first longitudinal centerline b and the second longitudinal centerline d are disposed to coincide with each other to ensure that the mating area 32 on the mating mask 30 and a partial area of the evaporation area 12 on the main mask 10 are accurately aligned and cooperated, thereby ensuring the accuracy of the cooperation and mounting between the two.

Specifically, the effective evaporation opening in the effective evaporation area 121 and the ineffective evaporation opening 122 in the ineffective evaporation area 123 arranged in the same direction, and the sizes and intervals are the same. In other words, the arrangement and the size of the effective evaporation opening and the ineffective evaporation opening 122 are completely identical. The effective evaporation area 121 and the ineffective evaporation area 123 are only virtual area boundaries corresponding to the structure of the display screen body. With respect to the mating area 32 disposed corresponding to the evaporation area 12, the first mating opening in the first mating area 321 is provided corresponding to the evaporation opening 31 in the effective evaporation area 121 to allow the material to be deposited on the substrate after passing through the openings in the two areas. The second mating opening 122 in the second mating area 323 is completely misaligned with the ineffective evaporation opening 122 in the ineffective evaporation area 123, so that the portion of the evaporation opening 31 of the ineffective evaporation area 123 is shielded by the solid portion in the second mating area 323, and the evaporation material is prevented from being deposited on the substrate through the main mask 10 and the mating mask 30.

The aforementioned mask structure 100 can be used for evaporation of the irregular-shaped display screen, or the aforementioned mask structure 100 can be used when the intervals between the plurality of display screens to be manufactured is narrow. The effective evaporation area 121 of the main mask 10 corresponds to the shape of the finally obtained display screen, the ineffective evaporation area 123 corresponds to the notch area of the irregular-shaped display screen, or the isolation area between the adjacent two display screens, or a combination of the above-mentioned isolation area and notch area. The orthographic projection of the effective evaporation opening on the mating mask 30 completely falls within the orthographic projection of the first mating opening in the mating mask 30. After passing through the first mating opening in the first mating area 321 in the evaporation process, the material can continue to pass through the effective evaporation opening in the effective evaporation area 121, and finally be deposited on the substrate. The ineffective evaporation opening 122 is shielded by the second mating area 323 to prevent deposition of material in the ineffective evaporation area during evaporation. In other words, in the manufacturing process of the irregular-shaped screen, or when the interval between the manufactured plurality of display screens is narrow, a wider mating mask 30 is provided to provide sufficient support to improve the evaporation yield. In addition, the evaporation area 12 including the effective evaporation area 121 and the ineffective evaporation area 123 is disposed on the main mask 10, the stress at the edge of the effective evaporation area 121 can be averaged by the ineffective evaporation opening in the ineffective evaporation area 123, thereby preventing the main mask 10 from being wrinkled due to uneven opening area during tensioning, thereby further improving the evaporation yield.

The present disclosure further provides the main mask 10 in the aforementioned mask assembly 100. The main mask 10 has the evaporation area 12, which includes the effective evaporation area 121 and the ineffective evaporation area 123. The effective evaporation area 121 corresponds to the display area of the display panel. The effective evaporation area 121 is provided with a plurality of effective evaporation openings penetrating the main mask 10, and the ineffective evaporation area 123 is provided with a plurality of ineffective evaporation openings 122 penetrating the main mask 10. With respect to the irregular-shaped display screen having the slotted area, the ineffective evaporation area 123 can correspond to the slotted area of the irregular-shaped display screen, and the ineffective evaporation opening 122 is distributed in the ineffective evaporation area 123 at the same time, so that the edge of the entire evaporation area 12 may be uniformly stressed to prevent wrinkles, thereby increasing the evaporation yield.

The present disclosure further provides the mating mask 30 in the aforementioned mask assembly 100, and the mating mask 30 is laminated with the main mask 10. The main mask 10 includes the effective evaporation area 121 and the ineffective evaporation area 123. A plurality of effective evaporation openings are distributed in the effective evaporation area 121, and a plurality of ineffective evaporation openings are distributed in the ineffective evaporation area 123. The mating mask 30 has a mating area 32, which includes the first mating area 321 and the second mating area 323. The first mating area 323 is provided with a plurality of first mating openings. An orthographic projection of each of the first mating openings on the mating mask 30 is configured to completely cover an orthographic projection of the effective evaporation opening on the mating mask 30. The second mating area 323 is configured to shield the plurality of ineffective evaporation openings 122 in the ineffective evaporation area 123.

When the mating mask 30 is placed under the main mask 10, the first mating area 321 of the mating mask 30 corresponds to at least a portion of the effective evaporation area 121 and is placed under a portion of the evaporation area 12, and the width of the mating mask 30 can be greater to provide sufficient support. In addition, the first mating area 321 is provided with the first mating opening communicating with the effective evaporation opening. The first mating area 321 allows the evaporation material to pass through, and the mating mask 30 provides the sufficient support without affecting the function of the evaporation material of the evaporation area 12.

Referring to FIG. 9, in one embodiment, the mating area 32 includes the first mating area 321 and the second mating area 323. There are two first mating areas 321, and the second mating area 323 is located between the adjacent two first mating areas 321. The first mating area 321 corresponds to the effective evaporation area 121 of the main mask 10, and the second mating area 323 corresponds to the ineffective evaporation area 123 of the main mask 10. A plurality of individual display panels can be simultaneously fabricated by shielding the ineffective evaporation openings in the ineffective evaporation area 123 by the second mating area 323.

Referring to FIG. 10, in another embodiment, the mating area 32 includes the first mating area 321 and the second mating area 323. The second mating area 323 corresponds to the slotted area of the display panel, and the first mating area 321 surrounds the second mating area 323. In this way, the mating mask 30 can be placed at the end of the main mask 10 and shield the ineffective evaporation area 123 on the main mask 10 by the second mating area 323. The second mating area 323 corresponds to the slotted area of the display panel, and the ineffective evaporation area 123 corresponds to the slotted area of the display panel, so that the irregular-shaped display panel having the slotted area can be obtained. In addition, the evaporation area 12 on the main mask 10 does not need to be disposed corresponding to the display area of the irregular-shaped display panel, the edge of the evaporation area 12 is uniformly stressed, the evaporation effect is good, and the product yield is high.

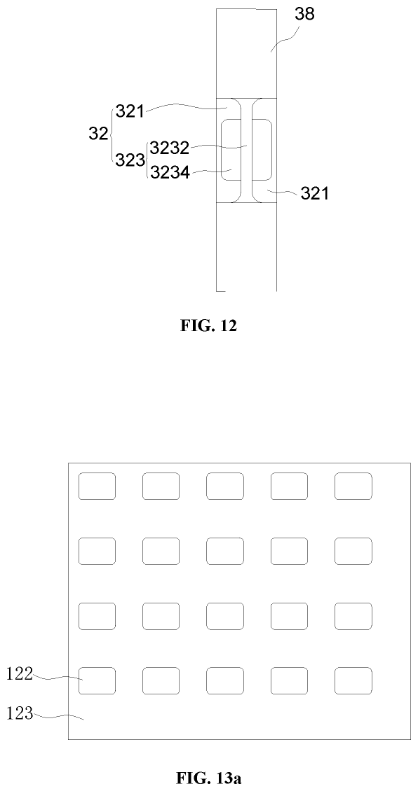

Referring to FIGS. 11 and 12, in yet another embodiment, the mating area 32 includes the first mating area 321 and the second mating area 323. There are two first mating areas 321. The second mating area 323 includes the second main mating area 3232 and the second auxiliary mating area 3234. The second main mating area 3232 is located between the adjacent two first mating areas 321, and the second auxiliary mating area 3234 corresponds to the slotted area of the display panel. In addition, the second auxiliary mating area 3234 is located on either side or opposite sides of the second main mating area 3232. After the second main mating area 3232 shields the ineffective evaporation opening on the main mask 10, the adjacent two sub-masks 20 are separated. In addition, the second auxiliary mating area 3234 corresponds to the slotted area of the display panel to shield the irregular-shaped opening area on the sub-mask 20, thus manufacturing the display panel having the slotted area.

The technical features of the above-described embodiments may be combined in any combination. For the sake of brevity of description, all possible combinations of the various technical features in the above embodiments are not described. However, as long as there is no contradiction in the combination of these technical features, it should be considered as the scope of the present specification.

The foregoing embodiments are merely illustrative of several embodiments of the present disclosure, and the description thereof is more specific and detailed, but is not to be construed as limiting the scope of the disclosure. It should be noted that any variation or replacement readily figured out by a person skilled in the art without departing from the concept of the present disclosure shall all fall within the protection scope of the present disclosure. Therefore, the protection scope of the present disclosure shall be subject to the protection scope of the appended claims.

1. A mask assembly, comprising:
a main mask having an evaporation area defining a plurality of evaporation openings, the evaporation area comprising an effective evaporation area and an ineffective evaporation area, a first evaporation opening located in the effective evaporation area being an effective evaporation opening, a second evaporation opening located in the ineffective evaporation area being an ineffective evaporation opening; and
a mating mask comprising a first mating area and a second mating area, the first mating area corresponding to the effective evaporation area, the second mating area corresponding to the ineffective evaporation area;
wherein:
the effective evaporation area corresponds to a display area of a display panel, the first mating area is provided with a first mating opening, an orthographic projection of the first mating opening on the mating mask completely covers an orthographic projection of the effective evaporation opening on the mating mask, and the second mating area shields the ineffective evaporation opening in the ineffective evaporation area.

2. The mask assembly of claim 1, wherein:
the main mask comprises an evaporation surface and a glass surface,
the evaporation surface is disposed facing to an evaporation source,
the glass surface is disposed away from the evaporation source, and
the mating mask is laminated with the evaporation surface of the main mask.

3. The mask assembly of claim 1, wherein:
the main mask comprises at least two sub-masks,
the ineffective evaporation area comprises a first ineffective evaporation area located between adjacent two sub-masks of the main mask,
a portion of the adjacent two sub-masks adjacent to the first ineffective evaporation area is not provided with an irregular-shaped opening area,
a plurality of the ineffective evaporation openings are distributed in the first ineffective evaporation area,
the mating mask comprises a first mating mask,
the first mating area of the first mating mask corresponds to a portion of the effective evaporation area of the adjacent two sub-masks adjacent to the first ineffective evaporation area, and
the second mating area corresponds to the first ineffective evaporation area and shields the ineffective evaporation openings in the first ineffective evaporation area.

4. The mask assembly of claim 1, wherein the main mask comprises at least one sub-mask defining an irregular-shaped opening area, the irregular-shaped opening area constituting at least a part of the ineffective evaporation area.

5. The mask assembly of claim 4, wherein the ineffective evaporation area comprises a second ineffective evaporation area, the second ineffective evaporation area is located at an end of the main mask and corresponds to the irregular-shaped opening area of the sub-mask at the end;
the mating mask comprises a second mating mask, the first mating area of the second mating mask corresponds to the effective evaporation area of the sub-mask located at the end of the main mask, the second mating area corresponds to the second ineffective evaporation area and shields the ineffective evaporation opening in the second ineffective evaporation area.

6. The mask assembly of claim 4, wherein the main mask comprises at least two sub-masks, the ineffective evaporation area comprises a third ineffective evaporation area, the third ineffective evaporation area comprises a third main ineffective evaporation area and a third auxiliary ineffective evaporation area, the third main ineffective evaporation area is located between adjacent two sub-masks, the third auxiliary ineffective evaporation area corresponds to the irregular-shaped opening area of the sub-mask;
the mating mask comprises a third mating mask, the first mating area of the third mating mask corresponds to a portion of the effective evaporation area of the adjacent two sub-masks, the second mating area corresponds to the third main ineffective evaporation area and the third auxiliary ineffective evaporation area, and shields the ineffective evaporation opening in the third main ineffective evaporation area and the third auxiliary ineffective evaporation area.

7. The mask assembly of claim 6, wherein in the sub-masks located at both sides of the third main ineffective evaporation area, the irregular-shaped opening area of any one of the sub-masks is adjacent to the third main ineffective evaporation area.

8. The mask assembly of claim 6, wherein the irregular-shaped opening areas of the two sub-masks located at both sides of the third main ineffective evaporation are disposed at both sides of the third main ineffective evaporation area, respectively.

9. The mask assembly of claim 4, wherein a projection of the irregular-shaped opening area on a main body of the main mask has a shape of circular or polygonal with an arcuate chamfer.

10. The mask assembly of claim 4, wherein the evaporation area comprises a first transverse centerline and a first longitudinal centerline perpendicular to each other, the evaporation area is axisymmetric relative to the first transverse centerline and/or the first longitudinal centerline.

11. The mask assembly of claim 10, wherein the mating mask comprises a mating area and a second transverse centerline and a second longitudinal centerline perpendicular to each other, the mating area being axisymmetric relative to the second transverse centerline and/or the second longitudinal centerline.

12. The mask assembly of claim 11, wherein when the main mask is laminated with the mating mask, the first longitudinal centerline coincides with the second longitudinal centerline.

13. The mask assembly of claim 1, wherein the second mating area is provided with a plurality of second mating openings, an orthographic projection of the second mating opening on the mating mask is completely offset from an orthographic projection of the ineffective evaporation opening on the mating mask.

14. The mask assembly of claim 1, wherein the orthographic projection of the first mating opening on the mating mask completely coincides with the orthographic projection of the effective evaporation opening on the mating mask.

15. A main mask, wherein the main mask has an evaporation area, the evaporation area comprises an effective evaporation area and an ineffective evaporation area, the effective evaporation area is provided with a plurality of effective evaporation openings penetrating the main mask, the ineffective evaporation area is provided with a plurality of ineffective evaporation openings penetrating the main mask, and the effective evaporation area corresponds to a display area of a display panel.

16. A mating mask, configured to be laminated with a main mask, wherein the main mask comprises an effective evaporation area and an ineffective evaporation area, a plurality of effective evaporation openings are distributed in the effective evaporation area, a plurality of ineffective evaporation openings are distributed in the ineffective evaporation area;
wherein the mating mask has a mating area, the mating area comprises a first mating area and a second mating area, the first mating area is provided with a plurality of first mating openings, an orthographic projection of each of the first mating openings on the mating mask completely covers an orthographic projection of each of the effective evaporation openings on the mating mask, the second mating area shields the plurality of ineffective evaporation openings in the ineffective evaporation area.

17. The mating mask of claim 16, wherein the mating area comprises the first mating area and the second mating area, the second mating area corresponds to a slotted area of a display panel, the first mating area surrounds the second mating area.

18. The mating mask of claim 16, wherein the mating area comprises the first mating area and the second mating area, there are two first mating areas, the second mating area is located between adjacent two first mating areas.

19. The mating mask of claim 16, wherein the mating area comprises the first mating area and the second mating area, there are two first mating areas, the second mating area comprises a second main mating area and a second auxiliary mating area, the second main mating area is located between adjacent two first mating areas, the second auxiliary mating area corresponds to an irregular-shaped slotted area of a display panel, and the second auxiliary mating area is located on either side or opposite sides of the second main mating area.
